(19) United States
(12) Patent Application Publication
(10) Pub. No.: US 2006/0042317 A1
(43) Pub. Date: Mar. 2, 2006

(54) Method of producing a glass substrate for a magnetic disk, Method of producing a magnetic disk, and a cylindrical glass material for a glass substrate

(75) Inventor: Takemi Miyamoto, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION

(21) Appl. No.: 11/212,604

(22) Filed: Aug. 29, 2005

(30) Foreign Application Priority Data
Aug. 30, 2004 (JP) 2004-249571
Jul. 11, 2005 (JP) 2005-202162

(51) Int. Cl. G11B 5/706; H01L 21/302; C03C 19/00

(52) U.S. Cl. 65/61; 428/846.9; 428/848.2; 428/848.6; 438/693; 451/41

(57) ABSTRACT

On producing a glass substrate for a magnetic disk, a side surface of a cylindrical glass material (3) is polished or mirror-finished before the cylindrical glass material is cut in a direction perpendicular to a center axis of the cylindrical glass material to produce a glass disk which constitutes the glass substrate.

This application claims priority to prior Japanese applications JP 2004-249571 and JP 2005-202162, the disclosures of which are incorporated herein by reference.

### BACKGROUND OF THE INVENTION

This invention relates to a method of producing a glass substrate for a magnetic disk which is used as a recording medium in an information recording apparatus such as a hard disk drive (HDD).

This invention also relates to a method of producing a magnetic disk which is used as a recording medium in an information recording apparatus such as a hard disk drive (HDD).

This invention also relates to a cylindrical glass material for a glass substrate as a material of a magnetic disk which is used as a recording medium in an information recording apparatus such as a hard disk drive (HDD).

In recent years, following development of an advanced information society, various types of information processing apparatuses have been proposed. As an information recording apparatus used in those information processing apparatuses, a hard disk drive (HDD) has been proposed. In order to reduce the size of the information processing apparatuses and to improve the performance thereof, the hard disk drive is required to have a large information recording capacity and a high recording density. In addition, it is desired to lower a manufacturing cost of the hard disk drive.

In order to achieve a high recording density of the hard disk drive, a so-called spacing loss must be reduced. To this end, it is required to reduce a glide height of a magnetic head for carrying out recording and reproducing operations upon a magnetic disk as a recording medium. During the recording and reproducing operations, the magnetic disk is rotated at a high speed. If the glide height of the magnetic head is reduced, the magnetic head may possibly be brought into contact with a surface of the magnetic disk. In order to prevent such contact between the magnetic head and the surface of the magnetic disk, the surface of the magnetic disk must be finished into an extremely flat and smooth surface.

In order to achieve such an extremely flat and smooth surface of the magnetic disk, an aluminum substrate, which has widely been used as a magnetic disk substrate, is replaced by a glass substrate, typically in a 2.5-inch disk. As compared with the aluminum substrate, the glass substrate is excellent in surface flatness and substrate strength. As the above-mentioned glass substrate, a chemically-strengthened glass substrate enhanced in substrate strength by chemical strengthening and a crystallized glass substrate improved in substrate strength by crystallization are known.

Generally, the glass substrate for a magnetic disk is produced by successively executing a step of heating and melting a glass material to prepare a molten glass, a step of forming the molten glass into a plate-like glass disk, and a step of processing and polishing the plate-like glass disk to prepare the glass substrate.

In order to form the molten glass into the plate-like glass disk, a forming method such as a pressing method, a floating method, and a fusion method is used. In case where the pressing method is used, the plate-like glass disk is directly produced from the molten glass. In case where the floating method or the fusion method is used, the molten glass is formed into a rectangular sheet glass and the glass disk is cut from the sheet glass. At present, it is a most common technique to prepare the glass disk by the pressing method.

As another technique, Japanese Unexamined Patent Application Publication (JP-A) No. H4-168629 discloses a method of cutting a glass disk from a cylindrical glass material.

Each of Japanese Unexamined Patent Application Publication (JP-A) No. H8-007272 and Japanese Patent (JP-B) No. 2639270 discloses a method of preparing a glass disk by cutting a cylindrical glass material using a multi-wire saw.

By polishing end faces and principal surfaces of the glass disk prepared as mentioned above and executing a strengthening process such as chemical strengthening, the glass substrate for a magnetic disk is produced.

By the use of the above-mentioned glass substrate capable of achieving a high information recording density, the hard disk drive can store a sufficiently large amount of information even if a small-sized magnetic disk is used. Therefore, the hard disk drive of the type is not only mounted to a desk-top or stationary computer but also used in a wide variety of applications. For example, the hard disk drive may be used as an information storage of a mobile apparatus as a car-mounted or a portable apparatus having a small housing space, such as a car navigation system, a portable digital assistant (PDA), and a mobile telephone.

For example, the small-sized magnetic disk to be mounted to such a small-sized hard disk drive has an outer diameter of 30 mm or less, an inner diameter of 10 mm or less, and a disk thickness of 0.5 mm or less. Typically, use is made of a 1.0-inch disk having an outer diameter of 27.4 mm, an inner diameter of 7 mm, and a disk thickness of 0.381 mm or a 0.85-inch disk having an outer diameter of 22 mm, an inner diameter of 6 mm, and a disk thickness of 0.381 mm.

The small-sized hard disk drive for mobile applications is continuously exposed to the risk of receiving an impulsive force due to dropping, vibration, rapid movement and acceleration, and so on. Therefore, as compared with a relatively large magnetic disk such as an existing 2.5-inch disk (having an outer diameter of 65 mm, an inner diameter of 20 mm, and a disk thickness of 0.635 mm), the glass substrate for a magnetic disk and the magnetic disk to be used in the above-mentioned hard disk drive are required to have a sufficiently high shock resistance.

On the other hand, proposal is recently made of a hard disk drive in which start and stop operations are carried out according to a LUL (Load UnLoad) system. As compared with existing magnetic disks, a magnetic disk to be mounted to the hard disk drive of the LUL system is required to have a flatter, smoother, and cleaner surface. Specifically, a magnetic head in the hard disk drive of the LUL system has a glide height of 10 nm or less and, as compared with an existing hard disk drive of a CSS (Contact Start Stop) system, a defect called a head crash tends to frequently occur. Under the circumstances, the glass substrate for a magnetic disk and the magnetic disk for use in the hard disk drive of the LUL system are required to have sufficiently clean surfaces as compared with the existing ones.

Further, use is recently made of a hard disk drive comprising a magnetic head provided with a magnetoresistive device or a giant magnetoresistive device. In this context also, the glass substrate for a magnetic disk and the magnetic disk are required to have flatter, smoother, and cleaner surfaces as compared with the existing ones. This is because the magnetic head provided with the magnetoresistive device or the giant magnetoresistive device may cause a thermal asperity defect if the flatness, smoothness, and the cleanliness of the surface of the magnetic disk are insufficient. Therefore, the magnetic disk for use with the magnetoresistive device for reproducing information therefrom must have a sufficiently flat, smooth, and clean surface as compared with a magnetic disk for use with a thin-film device for reproducing information therefrom.

For the small-sized hard disk drive suitable for mobile applications such as a mobile telephone, there is a strong demand for further reduction in cost and mass production. Accordingly, it is necessary to supply glass substrates for a magnetic disk and magnetic disks in large quantities at a low cost.

At present, in order to produce a glass substrate for a magnetic disk, use is predominantly made of the technique of preparing a glass disk from a molten glass by the use of a pressing method as described above. Use is also made of the technique of preparing a sheet glass from a molten glass using a float method or the like and cutting the sheet glass into a glass disk. If the glass disk is produced by the above-mentioned techniques, there is a problem that a large amount of glass wastes or glass scraps are discharged. Thus, a large part of the molten glass used as a material is eventually disposed of without being processed into the glass disk. In other words, it is difficult to improve a material efficiency. Further, it is difficult to increase the number of glass disks which can be produced per unit time, i.e., to improve a mass productivity of the glass disks.

Thus, if the glass disks are produced by the technique predominantly used at present, it is difficult to achieve sufficiently easy production and a sufficiently low production cost.

In order to eliminate the above-mentioned problems, use may be made of the method of producing a glass disk from a cylindrical glass material as disclosed in the above-referenced publications. However, this method is disadvantageous in that the glass disk obtained by cutting the cylindrical glass material often suffers occurrence of defects, such as burrs or chipped parts, around an end face portion thereof and that the glass disk has a nonuniform thickness. Further, by the above-mentioned method, it is difficult to obtain a glass disk having opposite principal surfaces parallel to each other with high accuracy.

It is believed that an insufficient mirror-surface quality of the end face portion of the glass substrate for a magnetic disk is a factor inhibiting the improvement in shock resistance, flatness and smoothness, and cleanliness required for the glass substrate for a magnetic disk and for the magnetic disk as mentioned above. Specifically, breakage of the glass substrate for a magnetic disk due to mechanical shock often occurs first at the end face portion. The reason is considered as follows. The end face portion of the glass substrate for a magnetic disk has a curved surface. It is therefore difficult to finish the end face portion into an excellently flat and smooth surface while a production cost is suppressed. As a consequence, microcracks are often left at the end face portion.

In the glass disk obtained by cutting the cylindrical glass material, burrs or chipped parts may be caused to occur around the end face portion thereof. Even if the end face portion is polished, microcracks may remain unremoved.

The end face portion of the glass substrate for a magnetic disk has surface roughness not so small as that of the principal surfaces. Therefore, the end face portion may cause occurrence of dust or may easily trap micro dusts.

In order to polish the end face portion of the glass substrate for a small-sized magnetic disk, it is a general practice to hold a number of glass substrates coaxially stacked on one another and to simultaneously polish inner and outer end face portions of these glass substrates.

### SUMMARY OF THE INVENTION

It is therefore a first object of this invention to provide a glass substrate for a magnetic disk at a low cost, which substrate is excellent in shape of an end face portion thereof, degree of parallelization of opposite principal surfaces, and uniformity of thickness, to achieve excellent polishing for the end face portion of the glass substrate for a magnetic disk, and to provide glass substrates for a magnetic disk and magnetic disks in large quantities at a low cost.

It is a second object of this invention to provide glass substrates for a magnetic disk and magnetic disks, which are excellent in shock resistance, in large quantities at a low cost.

It is a third object of this invention to provide glass substrates for a small-sized magnetic disk having an outer diameter of, for example, 30 mm or less and small-sized magnetic disks in large quantities at a low cost.

It is a fourth object of this invention to provide glass substrates for a magnetic disk and magnetic disks, which are adapted to be mounted to a hard disk drive of a LUL system, in large quantities at a low cost.

It is a fifth object of this invention is to provide a cylindrical glass material for a glass substrate, which material makes it possible to achieve the first through the fourth objects.

In order to eliminate the above-mentioned problems and to achieve the above-mentioned objects, this invention has following structures.

A method of producing a glass substrate for a magnetic disk according to this invention, a method of producing a magnetic disk according to this invention, and a cylindrical glass material for a glass substrate according to this invention are as follows:

(1) A method of producing a glass substrate for a magnetic disk, the method including the step of cutting a cylindrical glass material in a direction perpendicular to a center axis of the glass material to produce a glass disk which constitutes the glass substrate, wherein the method comprises the step of:

polishing a side surface of the glass material prior to the cutting step.

(2) The method according to (1), wherein the glass material is provided with a circular hole formed along the center axis.

(3) The method according to (1), wherein the method further comprises the step of:

forming, prior to the cutting step, on the side surface of the glass material an annular groove which becomes a chamfered surface at a peripheral portion of the glass disk.

(4) The method according to (1), wherein the glass substrate is for use in the magnetic disk which has an outer diameter of 30 mm or less.

(5) A method of producing a magnetic disk, wherein at least a magnetic layer is formed on a principal surface of the glass substrate produced by the method claimed in (1).

(6) The method according to (2), wherein the method further comprises the step of:

forming, prior to the cutting step, on the side surface of the glass material an annular groove which becomes a chamfered surface at a peripheral portion of the glass disk.

(7) The method according to (2), wherein the glass substrate is for use in the magnetic disk which has an outer diameter of 30 mm or less.

(8) A method of producing a magnetic disk, wherein at least a magnetic layer is formed on a principal surface of the glass substrate produced by the method claimed in (2).

(9) The method according to (3), wherein the glass substrate is for use in the magnetic disk which has an outer diameter of 30 mm or less.

(10) A method of producing a magnetic disk, wherein at least a magnetic layer is formed on a principal surface of the glass substrate produced by the method described in (3).

(11) A method of producing a magnetic disk, wherein at least a magnetic layer is formed on a principal surface of the glass substrate produced by the method described in (4).

(12) A method of producing a glass substrate for a magnetic disk, the method including the step of cutting a cylindrical glass material in a direction perpendicular to a center axis of the glass material to produce a glass disk which constitutes the glass substrate, wherein the method comprises the step of:

mirror-finishing a side surface of the glass material prior to the cutting step.

(13) The method according to (12), wherein the glass material is provided with a circular hole formed along the center axis.

(14) The method according to (

12), wherein the method further comprises the step of:

forming, prior to the cutting step, on the side surface of the glass material an annular groove which becomes a chamfered surface at a peripheral portion of the glass disk.

(15) The method according to (12), wherein the glass substrate is for use in the magnetic disk which has an outer diameter of 30 mm or less.

(16) A method of producing a magnetic disk, wherein at least a magnetic layer is formed on a principal surface of the glass substrate produced by the method described in (12).

(17) The method according to (13), wherein the method further comprises the step of:

forming, prior to the cutting step, on the side surface of the glass material an annular groove which becomes a chamfered surface at a peripheral portion of the glass disk.

(18) The method according to (13), wherein the glass substrate is for use in the magnetic disk which has an outer diameter of 30 mm or less.

(19) A method of producing a magnetic disk, wherein at least a magnetic layer is formed on a principal surface of the glass substrate produced by the method described in (13).

(20) The method according to (14), wherein the glass substrate is for use in the magnetic disk which has an outer diameter of 30 mm or less.

(21) A method of producing a magnetic disk, wherein at least a magnetic layer is formed on a principal surface of the glass substrate produced by the method described in (14).

(22) A method of producing a magnetic disk, wherein at least a magnetic layer is formed on a principal surface of the glass substrate produced by the method described in (15).

(23) A cylindrical glass material for a glass substrate, the glass material being cut in a direction perpendicular to a center axis of the glass material to produce a glass disk which is a material of the glass substrate for a magnetic disk, wherein:

the cylindrical glass material has a side surface subjected to polishing.

(24) The cylindrical glass material according to (23), wherein the side surface is provided with an annular groove which becomes a chamfered surface at a peripheral portion of the glass disk.

(25) The cylindrical glass material according to (23), wherein the cylindrical glass material comprises a crystallized glass.

(26) A cylindrical glass material for a glass substrate, the glass material being cut in a direction perpendicular to a center axis of the glass material to produce a glass disk which is a material of the glass substrate for a magnetic disk, wherein:

the cylindrical glass material has a side surface having a surface roughness of 0.3 μm or less in Ra and/or 3 μm in Rmax, where Ra is representative of a center-line-mean roughness, Rmax being a maximum height representative of a difference between a highest point and a lowest point of the side surface.

(27) The cylindrical glass material according to (26), wherein the side surface is provided with an annular groove which becomes a chamfered surface at a peripheral portion of the glass disk.

(28) The cylindrical glass material according to (26), wherein the cylindrical glass material comprises a crystallized glass.

(29) The cylindrical glass material according to (27), wherein the cylindrical glass material comprises a crystallized glass.

According to this invention, in a method of producing a glass substrate for a magnetic disk which includes a step of cutting a cylindrical glass material in a direction perpendicular to a center axis of the glass material to produce a glass disk, a side surface of the glass material is polished prior to the cutting step. As compared with a method of polishing end face portions of glass disks one by one, an object to be polished is large so that a flat and smooth surface is easily obtained.

In particular, in case where the glass substrate for a magnetic disk is reduced in size, it takes a very long time to polish the end face portions of the glass disks one by one. Therefore, reduction in cost is difficult. On the other hand, in this invention, polishing is easy so that large quantities of glass substrates for a magnetic disk can be obtained at a low cost.

Even in case where the end face portions of the glass disks are polished one by one, this invention is advantageous in the following respect. The glass disk obtained by cutting the cylindrical glass material is prevented from occurrence of burrs or chipped parts around the end face portion thereof because the side surface of the glass material is polished. By polishing the end face portion, microcracks or other defects are prevented from being left at the end face portion.

According to this invention, in a method of producing a glass substrate for a magnetic disk which includes a step of cutting a cylindrical glass material in a direction perpendicular to a center axis of the glass material to produce a glass disk, a side surface of the glass material is mirror-finished prior to the cutting step. As compared with a method of mirror-finishing end face portions of glass disks one by one, an object to be mirror-finished is large so that a flat and smooth mirror surface is easily obtained.

In particular, in case where the glass substrate for a magnetic disk is reduced in size, it takes a very long time to mirror-finish the end face portions of the glass disks one by one. Therefore, reduction in cost is difficult. On the other hand, in this invention, mirror-finishing is easy so that large quantities of glass substrates for a magnetic disk can be obtained at a low cost.

Even in case where the end face portions of the glass disks are polished one by one, this invention is advantageous in the following respect. The glass disk obtained by cutting the cylindrical glass material is prevented from occurrence of burrs or chipped parts around the end face portion thereof because the side surface of the glass material is mirror-finished. By mirror-finishing the end face portion, microcracks or other defects are prevented from being left at the end face portion.

Further, in the method of producing a glass substrate for a magnetic disk according to this invention, the glass material may be provided with a circular hole formed along the center axis. In this case, an inner end face portion of the glass disk, which otherwise is difficult to be polished, can easily be polished or mirror-polished.

In the method of producing a glass substrate for a magnetic disk according to this invention, the side surface of the glass disk may be provided with an annular groove which becomes a chamfered surface at a peripheral portion of the glass disk. In this case, inner and outer chamfered surfaces of the glass disk, which otherwise are difficult to be polished, can easily be polished or mirror-polished.

In a method of producing a magnetic disk according to this invention, at least a magnetic layer is formed on a principal surface of a glass substrate produced by the above-mentioned method of producing a glass substrate for a magnetic disk. In this manner, it is possible to provide magnetic disks in large quantities at a low cost each of which is prevented from occurrence of a thermal asperity defect even if the magnetic disk is mounted to a hard disk drive of a LUL system.

In the cylindrical glass material for a glass substrate according to this invention, a side surface thereof is polished. Therefore, in case where the cylindrical glass material is cut to produce a glass disk, a flat and smooth surface is easily obtained because an object to be polished is large as compared with the method of polishing end face portions of glass disks one by one. Even in case where the end face portions of the glass disks are polished one by one, this invention is advantageous in the following respect. The glass disk obtained by cutting the glass material is prevented from occurrence of burrs or chipped parts around the end face portion because the side surface of the glass material is polished. By polishing the end face portion, microcracks or other defects are prevented from being left at the end face portion.

In a cylindrical glass material for a glass substrate according to this invention, the cylindrical glass material has a side surface having surface roughness of 0.3 μm or less in Ra and/or 3 μm in Rmax. Therefore, in case where the cylindrical glass material is cut to produce a glass disk, the end face portion of the glass disk has excellent surface roughness. Even in case where the end face portions of the glass disks are polished one by one, this invention is advantageous in the following respect. The glass disk obtained by cutting the glass material is prevented from occurrence of burrs or chipped parts around the end face portion because the side surface of the glass material has excellent surface roughness. By polishing the end face portion, microcracks or other defects are prevented from being left at the end face portion.

Thus, in case where the glass substrate for a magnetic disk is reduced in size, it takes a very long time to polish the end face portions of the glass disks one by one. Therefore, reduction in cost is difficult. On the other hand, in this invention, polishing is easy so that large quantities of glass substrates for a magnetic disk can be provided at a low cost.

In the cylindrical glass material for a glass substrate according to this invention, the side surface may be provided with an annular groove which becomes a chamfered surface at a peripheral portion of the glass disk. The glass material is cut along the groove. In this case, easy polishing or excellent surface roughness is achieved for inner and outer chamfered surfaces of the glass disk, which are otherwise difficult to be polished.

Further, the cylindrical glass material for a glass substrate may comprise a crystallized glass. In this case, it is possible to obtain a glass disk having a high hardness and a high rigidity by cutting the cylindrical glass material without requiring chemical strengthening.

As described above, according to this invention, it is possible to provide a glass substrate for a magnetic disk at a low cost, which substrate is excellent in shape of an end face portion thereof, degree of parallelization of opposite principal surfaces, and uniformity of thickness, to achieve excellent polishing for the end face portion of the glass substrate for a magnetic disk, and to provide glass substrates for a magnetic disk and magnetic disks in large quantities at a low cost.

According to this invention, it is possible to provide glass substrates for a magnetic disk and magnetic disks, which are excellent in shock resistance, in large quantities at a low cost.

According to this invention, it is possible to provide glass substrates for a small-sized magnetic disk having an outer diameter of, for example, 30 mm or less and small-sized magnetic disks in large quantities at a low cost.

According to this invention, it is possible to provide glass substrates for a magnetic disk and magnetic disks, which are adapted to be mounted to a hard disk drive of a LUL system, in large quantities at a low cost.

According to this invention, it is possible to provide a cylindrical glass material for a glass substrate, which material makes it possible to exhibit the above-mentioned effects.

### BRIEF DESCRIPTION OF THE DRAWINGS

FIG. 1 is a perspective view of a glass substrate for a magnetic disk, which is produced by a method according to this invention;

FIG. 2 is an enlarged sectional view of the glass substrate in FIG. 1, showing an inner end face portion adjacent to a circular hole;

FIG. 3 is a view showing a series of steps of the method according to this invention;

FIG. 4 is an enlarged sectional view of a glass material with a groove formed on its side surface; and

FIG. 5 is a perspective view showing a state where the cylindrical glass material is cut by a multi-wire saw.

### DESCRIPTION OF THE PREFERRED EMBODIMENT

Now, description will be made of a preferred embodiment of this invention with reference to the drawing.

A method of producing a glass substrate for a magnetic disk according to this invention may be used, for example, to produce a glass substrate for a magnetic disk to be mounted to a hard disk drive (HDD). The magnetic disk is a recording medium capable of recording an information signal with a high density and reproducing the information signal, for example, by a perpendicular magnetic recording system.

The glass substrate for a magnetic disk has an outer diameter between 15 mm and 30 mm, an inner diameter between 5 mm and 12 mm, and a thickness between 0.35 mm and 0.5 mm. The glass substrate is used to produce a magnetic disk having a predetermined diameter, for example, a 0.8-inch magnetic disk (having an outer diameter of 21.6 mm, an inner diameter of 6 mm, and a thickness of 0.381 mm) or a 1.0-inch magnetic disk (having an outer diameter of 27.4 mm, an inner diameter of 7 mm, and a thickness of 0.381 mm). Further, the glass substrate may be used to produce a 2.5-inch magnetic disk or a 3.5-inch magnetic disk. Herein, the inner diameter is an inner diameter of a circular hole formed at the center of the glass substrate.

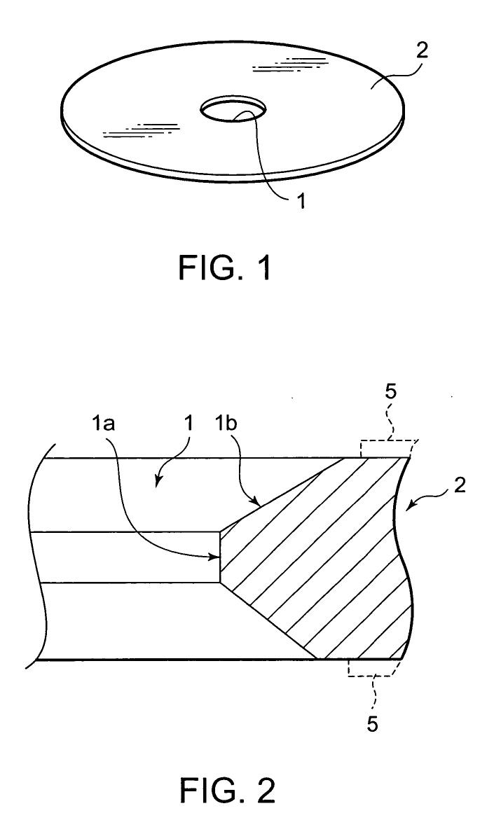

Referring to FIG. 1, a glass substrate 2 having a circular hole 1 formed at its center is produced by the method according to this invention. Because this substrate is made of a glass, it is possible to achieve an excellent flatness and smoothness by mirror-polishing the glass substrate 2. Further, the glass substrate has a high hardness and a high rigidity and is therefore excellent in shock resistance. In particular, a magnetic disk to be mounted to a hard disk drive equipped in a portable(handheld) or a car-mounted information processing apparatus is required to have a high shock resistance. Therefore, it is very useful to use the glass substrate in the above-mentioned magnetic disk. A glass itself is a brittle material but can be improved in breaking strength by a strengthening process, such as chemical strengthening and air-cool strengthening, or by crystallization.

As a material of the glass substrate, an aluminosilicate glass is preferable. This is because the aluminosilicate glass makes it possible to achieve an excellently flat and smooth mirror surface. In addition, the aluminosilicate glass can be improved in breaking strength, for example, by chemical strengthening. As a material of the glass substrate, a crystallized (amorphous) glass is preferable.

As the aluminosilicate glass, use is preferably made of a “chemically strengthening glass” containing 62-75 wt % SiO₂, 5-15 wt % Al₂O₃, 4-10 wt % Li₂O, 4-12 wt % Na₂O, and 5.5-15 wt % ZrO₂ as main components, where a weight ratio of Na₂O and ZrO₂ (Na₂O/ZrO₂) is 0.5-2.0 and a weight ratio of A₂O₃ and ZrO₂ (Al₂O₃/ZrO₂) is 0.4-2.5. In the present specification, the “chemically strengthening” glass means a glass to be subjected to chemical strengthening.

In order to avoid protrusions formed on a surface of the glass substrate due to an undissolved part of ZrO₂, use is preferably made of a chemically strengthening glass containing 57-74 mol % SiO₂, 0-2.8 mol % ZrO₂, 3-15 mol % Al₂O₃, 7-16 mol % Li₂O, and 4-14 mol % Na₂O. The aluminosilicate glass having the above-mentioned composition is increased in bending strength, increased in depth of a compressive stress layer, and excellent in Knoop hardness by chemical strengthening.

In this invention, the material of the glass substrate for a magnetic disk is not limited to that mentioned above. Specifically, as the material of the glass substrate, use may be made of a soda lime glass, a soda aluminosilicate glass, an alumino borosilicate glass, a borosilicate glass, a quartz glass, a chain silicate glass, or a glass ceramic such as a crystallized glass, in addition to the aluminosilicate glass mentioned above.

Referring to FIG. 2, the glass substrate 2 for a magnetic disk produced according to this invention preferably has chamfered edges on opposite sides of an end face portion. As illustrated in FIG. 2, an inner end face portion of the glass substrate 2 which is adjacent to the circular hole 1 is provided with a pair of chamfered portions or surfaces (C faces) 1b extending from the inner end face portion to opposite principal surfaces. On the other hand, an outer end face portion of the glass substrate 2 is provided with a pair of chamfered portions or surfaces (C faces) extending from the outer end face portion to the opposite principal surfaces, although not shown in the figure.

At the inner end face portion of the glass substrate 2, an area between the chamfered portions 1b is a cylindrical inner side surface (T face) 1a perpendicular to the principal surfaces of the glass substrate 2. The inner diameter of the circular hole 1 is an inner diameter of the inner side surface 1a. At the outer end face portion of the glass substrate 2, an area between the chamfered portions is a cylindrical outer side surface (T face) perpendicular to the principal surfaces of the glass substrate 2. The outer diameter of the glass substrate 2 is a diameter of the outer side surface. By chamfering the edges at the inner and the outer end face portions, the glass substrate is increased in breaking strength. In the following description, a combination of each of the side surfaces and the chamfered surfaces extending therefrom will be called the end face portion.

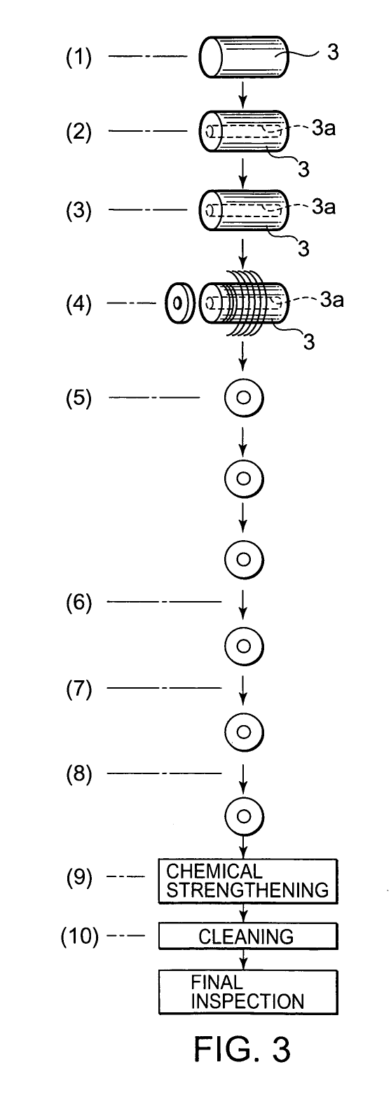

Referring to FIG. 3, description will be made of a series of steps of the method of producing the glass substrate for a magnetic disk according to this invention.

(1) Step of Obtaining a Cylindrical Glass Material

As illustrated in FIG. 3, a cylindrical glass material 3 is at first prepared. The glass material 3 preferably comprises an aluminosilicate glass as described above. The glass material 3 has a diameter slightly greater than that of the glass substrate 2 to be produced, and has a length corresponding to a total thickness of a large number of the glass substrates 2 stacked on one another.

(2) Step of Forming a Center Hole in the Glass Material

Next, a center hole 3a having a predetermined size is formed along a center axis of the glass material 3. The center hole 3a serves as the center hole 1 of the glass substrate 2 and has an inner diameter slightly smaller than that of the center hole 1.

Alternatively, without forming the center hole 3a in the glass material 3, the glass material 3 is cut or sliced into a plurality of glass disks. After cutting, the center hole 1 is formed in each glass disk.

(3) Step of Polishing (Mirror-Finishing) the Inner and the Outer Side Surfaces of the Glass Material

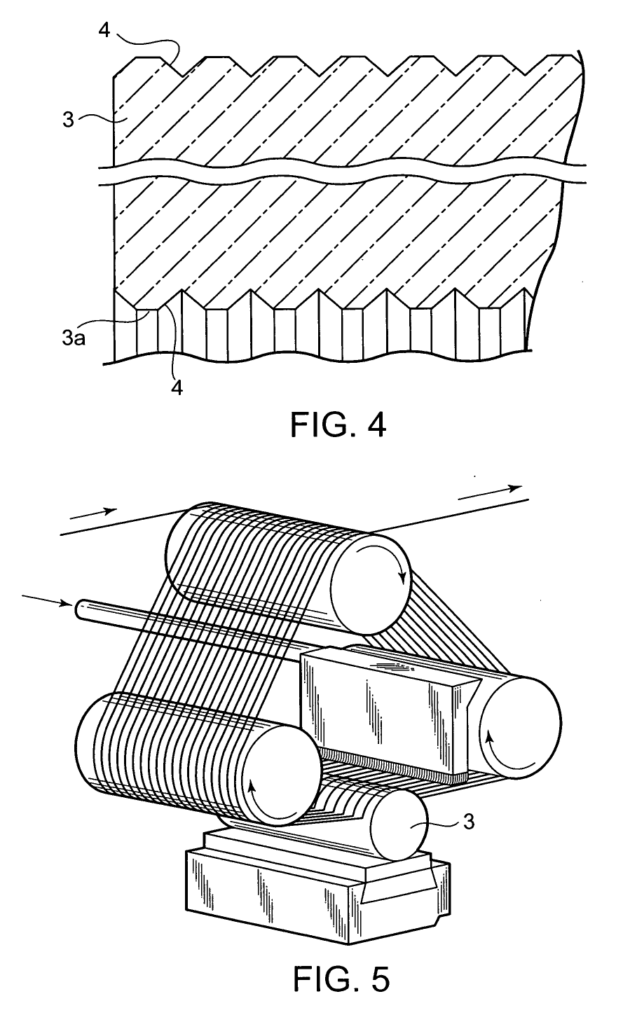

Next, the inner and the outer side surfaces of the glass material 3 are polished and mirror-finished. The polishing in this step is carried out by the use of a polisher and a brush or the like. Preceding the polishing step, the inner and the outer side surfaces of the glass material 3 may be provided with V-shaped grooves 4 formed in an annular shape along a circumferential direction, as illustrated in FIG. 4. The V-shaped grooves 4 serve as inner and outer chamfered surfaces or portions when the glass substrate 2 is produced.

As abrasive grains contained in the polisher used in this step, any abrasive grains having a polishing ability against the glass material may be used without specific limitation. For example, use may be made of cerium oxide (CeO₂) abrasive grains, colloidal silica abrasive grains, alumina abrasive grains, or diamond abrasive grains. In particular, the cerium oxide abrasive grains are preferable. The particle size of the abrasive grains may appropriately be selected. For example, the particle size is preferably in the range between 0.5 μm and 3 μm. Preferably, the polisher is used in the form of a slurry obtained by adding a liquid such as water (pure water) to the polisher containing the abrasive grains.

As a result of polishing, the inner and the outer side surfaces of the glass material 3 have surface roughness of 0.3 μm or less in Ra and 3 μm or less in R max. More preferably, the inner and the outer side surfaces of the glass material 3 are finished into mirror surfaces having surface roughness of 0.1 μm or less in Ra and/or 1 μm or less in Rmax.

(4) Step of Cutting (Slicing) the Glass Material

Next, the glass material 3 is cut in a direction perpendicular to the center axis to obtain a glass disk having a thickness slightly greater than that of the glass substrate 2 to be produced. At this time, a number of glass disks are obtained from a single piece of the glass material 3.

In this step, the glass material 3 is cut, for example, by the use of a multi-wire saw as shown in FIG. 5. The multi-wire saw comprises a plurality of multi-groove rollers arranged at a predetermined space from one another and a number of endless wires wound around the multi-groove rollers along a number of grooves formed on the multi-groove rollers. By running the endless wires and pressing the endless wires against the outer side surface of the glass material 3, the glass material 3 is cut.

(5) Shaping and Lapping Step

In this step, the glass disk obtained by cutting the glass material 3 is trimmed in shape and the principal surfaces of the glass disk are subjected to lapping. The glass disk is lapped by the use of a double-sided lapping apparatus and alumina abrasive grains so that the glass disk has a predetermined dimensional accuracy and a predetermined profile accuracy.

As described above, without forming the center hole 3a in the glass material 3, the center hole 1 may be formed in the glass disk in this step. Further, without forming the V-shaped grooves on the side surfaces of the glass material 3, outer and inner end face portions of the glass disk may be chamfered in this step.

Further, the outer and the inner end face portions of the glass disk may be polished in this step.

(6) First Polishing Step

Next, as a principal surface polishing step, a first polishing step is carried out. The first polishing step is primarily intended to remove flaws or distortions left on the principal surfaces in the lapping step. This step may be carried out by the use of a double-sided polishing apparatus, a hard resin polisher, and a planetary gear mechanism. As the polisher, use is preferably made of cerium oxide abrasive grains.

(7) Second Polishing Step

Next, as a principal surface mirror-polishing step, a second polishing step is carried out. The second polishing step is intended to finish the principal surfaces into mirror surfaces. This step may be carried out by the use of a double-sided polishing apparatus, a soft resin foam polisher, and a planetary gear mechanism. As the polisher, use is preferably made of cerium oxide abrasive grains finer than the cerium oxide abrasive grains used in the first polishing step.

(8) First Cleaning Step

After the second polishing step, the glass substrate is successively dipped into cleaning baths of a neutral detergent, a neutral detergent, pure water, pure water, IPA (isopropyl alcohol), and IPA (vapor drying) to be cleaned. Each cleaning bath is preferably applied with ultrasonic waves.

(9) Chemically Strengthening Step

Next, the glass disk after the lapping and the polishing steps is subjected to chemical strengthening. For example, chemical strengthening is carried out by preparing a chemically strengthening solution comprising a mixture of potassium nitrate (60%) and sodium nitrate (40%), heating the chemically strengthening solution to about 400° C., and dipping the glass disk cleaned and preheated to 300° C. for about 3 hours. In order to chemically strengthen an entire surface of the glass disk during dipping, the glass disks are preferably received in a holder holding end faces of the glass disks.

By dipping the glass disk in the chemically strengthening solution, lithium ions and sodium ions in a surface layer of the glass disk are replaced by sodium ions and potassium ions in the chemically strengthening solution so that the glass disk is strengthened.

The above-mentioned chemically strengthening step is unnecessary if the glass material comprises a crystallized glass. The chemically strengthening step may be carried out prior to the step of cutting (slicing) the glass material.

(10) Second Cleaning Step

After the chemically strengthening step, the glass disk is dipped into concentrated sulfuric acid heated to about 40° C. to be cleaned. After cleaning by the sulfuric acid, the glass disk is successively dipped into cleaning baths of pure water, pure water, IPA (isopropyl alcohol), and IPA (vapor drying) to be cleaned. Each cleaning bath is preferably applied with ultrasonic waves.

The second cleaning step is unnecessary if no chemically strengthening step is carried out.

(11) Step of Producing a Magnetic Disk

By the use of the glass substrate prepared in the above-mentioned manner, at least a magnetic layer is formed on each of the principal surfaces of the glass substrate. Thus, a magnetic disk prevented from occurrence of head crash or a thermal asperity defect is produced.

As the magnetic layer, a Co—Pt alloy magnetic layer having a high anisotropic magnetic field (Hk) is preferable. Between the glass substrate and the magnetic layer, an underlayer may appropriately be formed in order to improve crystal orientation of the magnetic layer and to achieve uniformity and fineness of grains. The underlayer and the magnetic layer may be formed, for example, by DC magnetron sputtering.

On the magnetic layer, a protection layer for protecting the magnetic layer is preferably formed. The protection layer may be a carbon-based protection layer. As a material of the carbon-based protection layer, hydrogenated carbon or nitrogenated carbon may be used. The protection layer may be formed by plasma CVD or DC magnetron sputtering.

On the protection layer, a lubrication layer for absorbing an impact from a magnetic head is preferably formed. The lubrication layer may be a perfluoropolyether lubrication layer. In particular, use is preferably made of alcohol-modified perfluoropolyether lubrication layer having a hydroxyl group excellent in affinity with the protection layer. The lubrication layer may be formed by dipping.

### EXAMPLES

Hereinafter, examples of this invention will be described in detail.

### First Example

In a first example, a glass substrate for a magnetic disk was prepared through following steps.

(1) Step of Obtaining a Cylindrical Glass Material

In this example, a glass material comprising an aluminosilicate glass was prepared.

The glass material had a diameter of 28.6 mm.

(2) Step of Forming a Center Hole in the Glass Material.

Next, a center hole was formed along a center axis of the glass material. The center hole had an inner diameter of 5.9 mm.

(3) Step of Polishing (Mirror-Finishing) Inner and Outer Side Surfaces of the Glass Material

An outer side surface of the glass material was mirror-polished by a brushing method using a polishing brush. At this time, a slurry (free abrasive grains) containing cerium oxide abrasive grains was used as abrasive grains.

Next, an inner side surface (inside the center hole) was mirror-polished by the brushing method using a polishing brush. Upon polishing the inner side surface of the glass material, the polishing brush was inserted into the center hole and a polisher was fed by a pump under a predetermined pressure. The polishing brush was rotated and the glass material was rotated. After lapse of a predetermined polishing time, the rotation of the polishing brush and the rotation of the glass material were stopped. Further, feeding of the polisher under the pressure was stopped. Thereafter, the polishing brush was pulled out from the center hole of the glass material.

As the polisher in this step, use was made of a slurry (free abrasive grains) containing cerium oxide abrasive grains. The particle size of the polisher must be within a range between 0.5 μm and 5 μm. In view of mirror finishing, the abrasive grains having a particle size between 0.5 μm and 2 μm were used.

Thereafter, dimensions of the side surfaces of the glass material were measured. As a result, the diameter (outer diameter) was 27.4 mm and the inner diameter of the center hole was 7 mm. It was confirmed that the side surfaces were mirror surfaces. It was also confirmed that the side surfaces had surface roughness of 0.01-0.02 μm in Ra and 0.3-0.4 μm in Rmax.

(4) Step of Cutting (Slicing) the Glass Material

Next, the glass material was cut in a direction perpendicular to the center axis. As a result, a glass disk having a thickness of 0.6 mm slightly greater than the thickness of the glass substrate to be produced was obtained. At this time, a number of glass disks were obtained from a single piece of the glass material 3.

In this step, the glass material 3 was cut by the use of a multi-wire saw.

In case where the surface roughness of the principal surfaces of the glass disk is sufficiently excellent as a result of the cutting step, a lapping step (which will later be described) may be omitted. In this case, cutting is performed so as to obtain the glass disk having a thickness of 0.45 mm near to the thickness of the glass substrate to be produced.

(5) Lapping Step

Herein, the glass disk obtained by cutting had an inner diameter of 7.0 mm, an outer diameter of 27.4 mm, and a thickness of 0.6 mm so as to obtain a 1.0-inch magnetic disk having a predetermined dimension after lapping and polishing the principal surfaces. It was confirmed that the principal surfaces had a flatness of 10 μm or less. Further, it was confirmed that the chamfered surfaces had a width of 0.21 mm and an angle of 45° with respect to the principal surfaces.

The principal surfaces of the glass disk were lapped. The lapping was performed by the use of a double-sided lapping apparatus and alumina abrasive grains so that the glass disk had a predetermined dimensional accuracy and a predetermined profile accuracy. The glass disk after lapping had an inner diameter of 7.0 mm, an outer diameter of 27.4 mm, and a thickness of 0.45 mm. Thus, the glass disk was confirmed to become a glass substrate for a 1.0-inch magnetic disk after polishing the principal surfaces.

A surface profile of each principal surface of the glass disk was observed. As a result, it was confirmed that the principal surfaces had a flatness of 3 μm or less. The surface roughness of the principal surfaces was about 2 μm in Rmax and about 0.3 μm in Ra.

Herein, outer and inner end face portions of the glass disk may be polished.

(6) First Polishing Step

Next, as a principal surface polishing step, a first polishing step was carried out. The first polishing step is primarily intended to remove flaws or distortions left on the principal surfaces in the lapping step. The principal surfaces were polished by the use of a double-sided polishing apparatus, a hard resin polisher, and a planetary gear mechanism. As the polisher, cerium oxide abrasive grains were used.

(7) Second Polishing Step

Next, as a principal surface mirror-polishing step, a second polishing step was carried out. The second polishing step is intended to finish the principal surfaces into mirror surfaces. The principal surfaces were mirror-polished by the use of a double-sided polishing apparatus, a soft resin foam polisher, and a planetary gear mechanism. As the polisher, use was made of cerium oxide abrasive grains finer than the cerium oxide abrasive grains used in the first polishing step.

The glass disk after polishing had a thickness of 0.381 mm.

(8) First Cleaning Step

After the second polishing step, the glass substrate was successively dipped into cleaning baths of a neutral detergent, a neutral detergent, pure water, pure water, IPA (isopropyl alcohol), and IPA (vapor drying) to be cleaned. Each cleaning bath was applied with ultrasonic waves.

(9) Chemically Strengthening Step

Next, the glass disk after the lapping and the polishing steps was subjected to chemical strengthening. The chemical strengthening was carried out by preparing a chemically strengthening solution comprising a mixture of potassium nitrate (60%) and sodium nitrate (40%), heating the chemically strengthening solution to 400° C, and dipping the glass disk cleaned and preheated to 300° C. for about 3 hours. In order to chemically strengthen an entire surface of the glass disk during dipping, the glass disks were received in a holder holding end faces of the glass disks.

By dipping the glass disk in the chemically strengthening solution, lithium ions and sodium ions in a surface layer of the glass disk were replaced by sodium ions and potassium ions in the chemically strengthening solution so that the glass disk was strengthened.

A compressive stress layer formed at the surface layer of the glass disk had a thickness of about 100-200 μm.

The glass disk after chemically strengthened was dipped into a water bath of 20° C. to be rapidly cooled and was held for about 10 minutes.

As mentioned above, the chemically strengthening step may be carried out prior to the step of cutting (slicing) the glass material.

(10) Second Cleaning Step

The glass disk after rapidly cooled was dipped into concentrated sulfuric acid heated to about 40° C. to be cleaned. After cleaning by the sulfuric acid, the glass disk was successively dipped into cleaning baths of pure water, pure water, IPA (isopropyl alcohol), and IPA (vapor drying) to be cleaned. Each cleaning bath was applied with ultrasonic waves.

(11) Final Inspection Step

The inner end face portion of the glass substrate obtained via the above-mentioned steps had a surface roughness of 0.4 μm in Rmax and 0.02 μm in Ra with respect to both of a chamfered surface (C face) and a cylindrical surface (T face). The surface roughness Rmax is a maximum height representative of a difference between a highest point and a lowest point of the surface as defined in Japanese Industrial Standard (JIS) B0601 and also disclosed in U.S. Pat. No. 6,544,893 B2. The surface roughness Ra is representative of a center-line-mean roughness as defined in Japanese Industrial Standard (JIS) B0601 and also disclosed in U.S. Pat. No. 6,544,893 B2.

The outer end face portion also had surface roughness of 0.4 μm in Rmax and 0.02 μm in Ra with respect to both of a chamfered surface (C face) and a cylindrical surface (T face). Each end face portion was finished into a mirror surface.

Measurement of the surface roughness was carried out by an atomic force microscope. Calculation of numerical values was carried out in accordance with Japanese Industrial Standard (JIS) B0601. The mirror surface was confirmed by both of observation using an electron microscope and observation using an optical microscope.

### Second Example

In a second example, a glass substrate for a magnetic disk was prepared through following steps.

(1) Step of Obtaining a Cylindrical Glass Material

In this example, a glass material comprising a crystallized glass was prepared.

The glass material had a diameter of 28.6 mm.

(2) Step of Forming a Center Hole in the Glass Material.

Next, a center hole was formed along a center axis of the glass material. The center hole had an inner diameter of 5.9 mm.

(3) Step of Polishing (mirror-Finishing) Inner and Outer Side Surfaces of the Glass Material

An outer side surface of the glass material was mirror-polished by a brushing method using a polishing brush. At this time, a slurry (free abrasive grains) containing cerium oxide abrasive grains was used as abrasive grains.

Next, an inner side surface (inside the center hole) was mirror-polished by the brushing method using a polishing brush. Upon polishing the inner side surface of the glass material, the polishing brush was inserted into the center hole and a polisher was fed by a pump under a predetermined pressure. The polishing brush was rotated and the glass material was rotated. After lapse of a predetermined polishing time, the rotation of the polishing brush and the rotation of the glass material were stopped. Further, feeding of the polisher under the pressure was stopped. Thereafter, the polishing brush was pulled out from the center hole of the glass material.

As the polisher in this step, use was made of a slurry (free abrasive grains) containing cerium oxide abrasive grains. The particle size of the polisher must be within a range between 0.5 μm and 5 μm. In view of mirror finishing, the abrasive grains having a particle size between 0.5 μm and 2 μm was used.

Thereafter, dimensions of the side surfaces of the glass material were measured. As a result, the diameter (outer diameter) was 27.4 mm and the inner diameter of the center hole was 7 mm. It was confirmed that the side surfaces were mirror surfaces. It was confirmed that the side surfaces had surface roughness of 0.01-0.02 μm in Ra and 0.3-0.4 μm in Rmax.

(4) Step of Cutting (Slicing) the Glass Material

Next, the glass material was cut in a direction perpendicular to the center axis. As a result, a glass disk having a thickness of 0.6 mm slightly greater than the thickness of the glass substrate to be produced was obtained. At this time, a number of glass disks were obtained from a single piece of the glass material 3.

In this step, the glass material 3 was cut by the use of a multi-wire saw. Since the crystallized glass has a high hardness, it is preferable to sufficiently cool the glass material 3 when it is cut by the use of the multi-wire saw. Accordingly, it is preferable to cut the glass material 3 while supplying a coolant instead of a grinding fluid used in ordinary cutting using a multi-wire saw or in addition to the grinding fluid.

In case where the surface roughness of the principal surfaces of the glass disk is sufficiently excellent as a result of the cutting step, a lapping step (which will later be described) may be omitted. In this case, cutting is performed so as to obtain the glass disk having a thickness of 0.45 mm near to the thickness of the glass substrate to be produced.

(5) Lapping Step

Herein, the glass disk obtained by cutting had an inner diameter of 7.0 mm, an outer diameter of 27.4 mm, and a thickness of 0.6 mm so as to obtain a 1.0-inch magnetic disk having a predetermined dimension after lapping and polishing the principal surfaces. It was confirmed that the principal surfaces had a flatness of 10 μm or less. Further, it was confirmed that the chamfered surfaces had a width of 0.21 mm and an angle of 45° with respect to the principal surfaces.

The principal surfaces of the glass disk were lapped. The lapping was performed by the use of a double-sided lapping apparatus and alumina abrasive grains so that the glass disk had a predetermined dimensional accuracy and a predetermined profile accuracy. The glass disk after lapping had an inner diameter of 7.0 mm, an outer diameter of 27.4 mm, and a thickness of 0.45 mm. Thus, the glass disk was confirmed to become a glass substrate for a 1.0-inch magnetic disk after polishing the principal surfaces.

A surface profile of each principal surface of the glass disk was observed. As a result, it was confirmed that the principal surfaces had a flatness of 3 μm or less. The surface roughness of the principal surfaces was about 2 μm in Rmax and about 0.3 μm in Ra.

Herein, outer and inner end face portions of the glass disk may be polished.

(6) First Polishing Step

Next, as a principal surface polishing step, a first polishing step was carried out. The first polishing step is primarily intended to remove flaws or distortions left on the principal surfaces in the lapping step. The principal surfaces were polished by the use of a double-sided polishing apparatus, a hard resin polisher, and a planetary gear mechanism. As the polisher, cerium oxide abrasive grains were used.

(7) Second Polishing Step

Next, as a principal surface mirror-polishing step, a second polishing step was carried out. The second polishing step is intended to finish the principal surfaces into mirror surfaces. The principal surfaces were mirror-polished by the use of a double-sided polishing apparatus, a soft resin foam polisher, and a planetary gear mechanism. As the polisher, use was made of cerium oxide abrasive grains finer than the cerium oxide abrasive grains used in the first polishing step.

The glass disk after polishing had a thickness of 0.381 mm.

(8) Cleaning Step

After the second polishing step, the glass substrate was successively dipped into cleaning baths of a neutral detergent, a neutral detergent, pure water, pure water, IPA (isopropyl alcohol), and IPA (vapor drying) to be cleaned. Each cleaning bath was applied with ultrasonic waves.

(9) Final Inspection Step

The inner end face portion of the glass substrate obtained via the above-mentioned steps had surface roughness of 0.4 μm in Rmax and 0.02 μm in Ra with respect to both of a chamfered surface (C face) and a cylindrical surface (T face).

The outer end face portion also had surface roughness of 0.4 μm in Rmax and 0.02 μm in Ra with respect to both of a chamfered surface (C face) and a cylindrical surface (T face). Each end face portion was finished into a mirror surface.

Measurement of the surface roughness was carried out by an atomic force microscope. Calculation of numerical values was carried out in accordance with Japanese Industrial Standard (JIS) B0601. The mirror surface was confirmed by both of observation using an electron microscope and observation using an optical microscope.

### Third Example

In a third example, a magnetic disk was produced by the use of the glass substrate for a magnetic disk produced in each of the first and the second examples.

On each of the opposite principal surfaces of the glass substrate mentioned above, a Ni—Ta alloy first underlayer, a Ru second underlayer, a Co—Cr—Pt—B alloy magnetic layer, and a hydrogenated carbon protection layer were successively formed by the use of a fixed-target DC magnetron sputtering apparatus. Next, an alcohol-modified perfluoropolyether lubrication layer was formed by dipping. Thus, the magnetic disk for a perpendicular magnetic recording system was obtained. In the manner shown in FIG. 2, at least the magnetic layer 5 is formed on each of the opposite principal surfaces of the glass substrates.

For the magnetic disk thus obtained, it was confirmed that no defect was caused in films of the magnetic layer and other layers due to foreign matters. The magnetic disk was subjected to a glide test. As a result, hit (a phenomenon that a magnetic head grazes or shaves a protrusion on a surface of the magnetic disk) or head crash (a phenomenon that the magnetic head collides against the protrusion on the surface of the magnetic disk) was not observed. Further, a recording/reproducing test was performed by the use of a magnetoresistive head. As a result, no malfunction due to a thermal asperity defect was observed.

The above-mentioned tests were carried out as a test method for a magnetic disk having an information recording density of about 40 Gbits per 1 square inch. Specifically, the glide height of the magnetic head was 10 nm. In the recording/reproducing test, the linear recording density was 700 fci.

Thus, it has been understood that the magnetic disk according to this invention is prevented from the problem due to the foreign matters on the surface of the glass substrate and that the magnetic disk according to this invention was produced as an excellent magnetic disk suitable for use with a magnetoresistive head.

While the present invention has thus far been described in connection with the preferred embodiment thereof, it will readily be possible for those skilled in the art to put this invention into practice in various other manners.

What is claimed is:

1. A method of producing a glass substrate for a magnetic disk, said method including the step of cutting a cylindrical glass material in a direction perpendicular to a center axis of said glass material to produce a glass disk which constitutes said glass substrate, wherein said method comprises the step of:
polishing a side surface of said glass material prior to said cutting step.

2. The method according to claim 1, wherein said glass material is provided with a circular hole formed along said center axis.

3. The method according to claim 1, wherein said method further comprises the step of:
forming, prior to said cutting step, on the side surface of said glass material an annular groove which becomes a chamfered surface at a peripheral portion of said glass disk.

4. The method according to claim 1, wherein said glass substrate is for use in the magnetic disk which has an outer diameter of 30 mm or less.

5. A method of producing a magnetic disk, wherein at least a magnetic layer is formed on a principal surface of said glass substrate produced by the method claimed in claim 1.

6. The method according to claim 2, wherein said method further comprises the step of:
forming, prior to said cutting step, on the side surface of said glass material an annular groove which becomes a chamfered surface at a peripheral portion of said glass disk.

7. The method according to claim 2, wherein said glass substrate is for use in the magnetic disk which has an outer diameter of 30 mm or less.

8. A method of producing a magnetic disk, wherein at least a magnetic layer is formed on a principal surface of said glass substrate produced by the method claimed in claim 2.

9. The method according to claim 3, wherein said glass substrate is for use in the magnetic disk which has an outer diameter of 30 mm or less.

10. A method of producing a magnetic disk, wherein at least a magnetic layer is formed on a principal surface of said glass substrate produced by the method claimed in claim 3.

11. A method of producing a magnetic disk, wherein at least a magnetic layer is formed on a principal surface of said glass substrate produced by the method claimed in claim 4.

12. A method of producing a glass substrate for a magnetic disk, said method including the step of cutting a cylindrical glass material in a direction perpendicular to a center axis of said glass material to produce a glass disk which constitutes said glass substrate, wherein said method comprises the step of:
mirror-finishing a side surface of said glass material prior to the cutting step.

13. The method according to claim 12, wherein said glass material is provided with a circular hole formed along said center axis.

14. The method according to claim 12, wherein said method further comprises the step of:
forming, prior to said cutting step, on the side surface of said glass material an annular groove which becomes a chamfered surface at a peripheral portion of said glass disk.

15. The method according to claim 12, wherein said glass substrate is for use in the magnetic disk which has an outer diameter of 30 mm or less.

16. A method of producing a magnetic disk, wherein at least a magnetic layer is formed on a principal surface of said glass substrate produced by the method claimed in claim 12.

17. The method according to claim 13, wherein said method further comprises the step of:
forming, prior to said cutting step, on the side surface of said glass material an annular groove which becomes a chamfered surface at a peripheral portion of said glass disk.

18. The method according to claim 13, wherein said glass substrate is for use in the magnetic disk which has an outer diameter of 30 mm or less.

19. A method of producing a magnetic disk, wherein at least a magnetic layer is formed on a principal surface of said glass substrate produced by the method claimed in claim 13.

20. The method according to claim 14, wherein said glass substrate is for use in the magnetic disk which has an outer diameter of 30 mm or less.

21. A method of producing a magnetic disk, wherein at least a magnetic layer is formed on a principal surface of said glass substrate produced by the method claimed in claim 14.

22. A method of producing a magnetic disk, wherein at least a magnetic layer is formed on a principal surface of said glass substrate produced by the method claimed in claim 15.

23. A cylindrical glass material for a glass substrate, said glass material being cut in a direction perpendicular to a center axis of said glass material to produce a glass disk which is a material of the glass substrate for a magnetic disk, wherein:
said cylindrical glass material has a side surface subjected to polishing.

24. The cylindrical glass material according to claim 23, wherein said side surface is provided with an annular groove which becomes a chamfered surface at a peripheral portion of said glass disk.

25. The cylindrical glass material according to claim 23, wherein said cylindrical glass material comprises a crystallized glass.

26. A cylindrical glass material for a glass substrate, said glass material being cut in a direction perpendicular to a center axis of said glass material to produce a glass disk which is a material of the glass substrate for a magnetic disk, wherein:
said cylindrical glass material has a side surface having a surface roughness of 0.3 μm or less in Ra and/or 3 μm in Rmax, where Ra is representative of a center-line-mean roughness, Rmax being a maximum height representative of a difference between a highest point and a lowest point of the side surface.

27. The cylindrical glass material according to claim 26, wherein said side surface is provided with an annular groove which becomes a chamfered surface at a peripheral portion of said glass disk.

28. The cylindrical glass material according to claim 26, wherein said cylindrical glass material comprises a crystallized glass.

29. The cylindrical glass material according to claim 27, wherein said cylindrical glass material comprises a crystallized glass.
